(19) United States
(12) Patent Application Publication
(10) Pub. No.: US 2001/0018249 A1
(43) Pub. Date: Aug. 30, 2001

(54) Semiconductor device with low resistivity film embedded and manufacturing method for the same

(76) Inventor: Takao Tanaka, Tokyo (JP)

Correspondence Address: HELFGOTT & KARAS, P.C., EMPIRE STATE BUILDING, 60TH FLOOR, NEW YORK, NY, 10118, US

(21) Appl. No.: 09/792,303

(22) Filed: Feb. 23, 2001

(30) Foreign Application Priority Data
Feb. 29, 2000 (JP) 057913/2000

(51) Int. Cl. H01L 21/336

(52) U.S. Cl. 438/259; 438/270

(57) ABSTRACT

A semiconductor device includes a first insulating film, a first conductive layer, a gate insulating film and a gate electrode. The first insulating film is formed on inner walls other than a top portion of each of grooves which are formed in a surface of a semiconductor substrate. The top portion is near to the surface of the semiconductor substrate. The first conductive layer is formed to fill a concave portion to the surface of the semiconductor substrate and to having a portion extending from the top portion into a portion of the semiconductor substrate. The concave portion is formed by the first insulating film in each of the grooves, and the first conductive layers function as source and drain regions. The gate insulating film is formed to cover the first conductive layer and the semiconductor substrate. The gate electrode is formed on the gate insulating film to form a MOS transistor.

### BACKGROUND OF THE INVENTION

1. Field of the Invention

The present invention relates to a semiconductor device and a manufacturing method for the same. More particularly, the present invention relates to a semiconductor device such as a flat cell type ROM in which a low resistivity film is embedded in a groove and a manufacturing method for the same.

2. Description of the Related Art

In a flat cell type ROM, source and drain regions of a cell transistor are not formed in a self-alignment manner after a gate is formed. The source and drain regions are formed through patterning and ion implantation before the gate is formed. The patterning is carried out by use of a photo-resist layer film, or a hard mask of a film such as an oxide film and a nitride film. Thus, N-type diffusion layers are formed in a semiconductor substrate as the source and drain regions.

In the flat cell type Rom, the source and drain regions as N-type diffusion layers are arranged in a Y direction on a P-type silicon substrate with a predetermined interval as bit lines Bit. Also, gate electrodes of polycide films, that is, word lines W are arranged in an X direction on the silicon substrate with a predetermined interval to intersect the bit lines Bit. A cell transistor Q having a MOS structure is formed in the region which contains each of the intersection points of the bit lines Bit and the word lines W.

FIGS. 1A and 1B are cross sectional views of the cell transistor having a MOS structure. Referring to FIG. 1A, a mask oxide film 202 is formed on a P-type silicon substrate 201, and a photo-resist layer 203 is applied on the mask oxide film 202. Then, opening portion are formed in the photo-resist layer 203 for the bit lines Bit (the source and drain regions), and N-type impurity is ion implanted using the photo-resist layer 203 with the opening portion to form N-type diffusion layers 204. Subsequently, as shown in FIG. 1B, the photo-resist layer 203 and the mask oxide film 202 are removed. Subsequently, the surface of the silicon substrate 201 is oxidized once more to form a gate oxide film 205. At this time, since the impurity density is high in the region of the N-type diffusion layers 204, oxidization is selectively accelerated. Accordingly, the gate oxide film 205 has the thicker thickness in the region of the N-type diffusion layers 204. Next, in the surface, a polycide film 206 is formed on the substrate, and this polycide film is patterned by a dry etching method using photolithography technique to form the word lines W as gate polycide layers. Thus, the cell transistor is formed. It should be noted that the cell transistor of an OFF state is formed if the P-type impurity is selectively implanted into the channel region.

However, the width of N-type diffusion layer 204 as the bit line Bit becomes narrow with employment of the design rule for fine patterns, so that the N-type diffusion layer 204 has had high resistance. This is a factor in reduction of the access speed to a memory cell.

Also, on the other hand, N-type impurity ions are diffused in a lateral direction in thermal treatment to activate the implanted impurity ions for forming the N-type diffusion layer, and the interval between the N-type diffusion layers 204 as the gate length of the cell transistor becomes narrow. As a result, there is a problem that the effective channel length of the cell transistor becomes short so that the leak current becomes large.

In conjunction with the above description, a trench EPROM is disclosed in Japanese Laid Open Patent Application (JP-A-Heisei 8-340057). In this reference, a semiconductor substrate has a flat surface and a first substrate region. A first FET has a first diffusion region, a second diffusion region and a first gate adjacent to a first gate insulator, which is adjacent to a first channel in the first substrate region. A second FET is connected in serial to the first FET. The second FET has a second gate adjacent to a second gate insulator, which is adjacent to a second channel in the first substrate region. The second gate is in a floating state and is not connected with the first gate. The second gate mainly couples in capacitance to a control electrode as a third diffusion region. The third diffusion region is embedded.

Also, a non-volatile semiconductor memory device is disclosed in Japanese Laid Open Patent Application (JP-A-Heisei 10-270575). In this reference, the non-volatile semiconductor memory device is composed of a plurality of device separation regions which segment a semiconductor active region. The memory device is further composed of a source region and a drain region formed in the semiconductor active region. A charge accumulation layer is coupled in capacitance to the semiconductor active region between the source region and the drain region through a first gate insulating film. A control gate is coupled in capacitance to the charge accumulation layer through a second gate insulating film. The second gate insulating film is formed from the surface of the device separation region under the control gate to the surface of the device separation region other than the surface of the device separation region under the control gate. The device separation region is a trench type device separation region.

Also, a non-volatile semiconductor memory device is disclosed in Japanese Laid Open Patent Application (JP-A-Heisei 11-154712). In this reference, the memory device is composed of impurity diffusion layers for a source electrode and a drain electrode in a semiconductor substrate. A first floating-gate electrode is formed on a channel region defined by the impurity diffusion layers through a gate insulating film. A second floating-gate electrode is formed on the impurity diffusion layer through a tunnel insulating film which is thinner than the gate insulating film. A third floating-gate electrode is connected with the first and second floating-gate electrodes. A control gate electrode is formed on the third floating-gate electrode through the insulating film. In the memory device, cells having the above structure are formed and are separated by a trench separating method in which an insulating film is embedded in a trench.

Also, a semiconductor device is disclosed in Japanese Laid Open Patent Application (JP-A-Heisei 11-307744). In this reference, a gate laminate layer is formed on a channel in a semiconductor substrate through a tunnel insulating film to contain a floating-gate. The floating-gate is provided to be near to either of a source diffusion layer or a drain diffusion layer. Another gate is provided on the channel through the gate insulating film outside the floating-gate. The source layer is composed of an impurity diffusion layer which is formed on the bottom surface and side surface of a trench formed in the semiconductor substrate and a conductive layer embedded in the trench.

### SUMMARY OF THE INVENTION

Therefore, an object of the present invention is to provide a semiconductor device and a manufacturing method of the same, in which the increase of resistance in a source or drain region as a wiring lie can be suppressed.

Another object of the present invention is to provide a semiconductor device and a manufacturing method of the same, in which the above source and drain regions are used.

Still another object of the present invention is to provide a semiconductor device and a manufacturing method of the same, in which a leak current in a channel can be made sufficiently small.

In an aspect of the present invention, a semiconductor device includes a first insulating film, a first conductive layer, a gate insulating film and a gate electrode. The first insulating film is formed on inner walls other than a top portion of each of grooves which are formed in a surface of a semiconductor substrate. The top portion is near to the surface of the semiconductor substrate. The first conductive layer is formed to fill a concave portion to the surface of the semiconductor substrate and to having a portion extending from the top portion into a portion of the semiconductor substrate. The concave portion is formed by the first insulating film in each of the grooves, and the first conductive layers function as bit lines. The gate insulating film is formed to cover the first conductive layer and the semiconductor substrate. The gate electrode is formed on the gate insulating film to form a MOS transistor.

The first conductive layer may be composed of a second conductive layer in the concave portion, a third conductive layer on the second conductive layer and the first insulating film in the groove, and the extending portion formed by solid phase diffusion of impurity from the third conductive layer. In this case, it is desirable that the second conductive layer is formed of at least one of metal, metal silicide and impurity-doped polysilicon. Also, it is desirable that the third conductive layer is formed of impurity-doped polysilicon.

Also, the semiconductor device may be further composed of a plurality of grooves which extend in a direction orthogonal to the gate electrode, and a plurality of gate electrodes parallel to each other. A flat cell type transistor is formed at a region where every two of the plurality of grooves intersect one of the plurality of gate electrodes. In this case, the semiconductor device may be a mask ROM.

In another aspect of the present invention, a semiconductor device includes a first conductive layer, a second conductive layer, a gate insulating film and a gate electrode. The first conductive layer is embedded in each of grooves formed in a surface portion of a semiconductor substrate. The second conductive layer is formed on the first conductive layer in each of the grooves, and the first and second conductive layers function as bit lines. The gate insulating film is formed to cover the second conductive layer and the semiconductor substrate. The gate electrode is formed on the gate insulating film to form a MOS transistor.

The second conductive layer may be further composed of extending conductive portions, each of which extends from a top portion of the second conductive layer into the surface portion of the semiconductor substrate. In this case, a region between the extending conduction portions of the grooves adjacent to each other functions as a channel region.

Also, the first conductive layer may be formed of at least one of metal, metal silicide and impurity-doped polysilicon. Also, the second conductive layer may be formed of impurity-doped polysilicon.

Also, the first conductive layer may be formed in a concave portion which is formed by an insulating film formed on inner walls of each of the grooves.

Also, the semiconductor device may be further composed of a plurality of grooves which extend in a direction orthogonal to the gate electrode, and a plurality of the gate electrodes parallel to each other. A flat cell type transistor is formed in a region where every two of the plurality of grooves intersect one of the plurality of gate electrodes. Also, the semiconductor device may be a mask ROM.

In still another aspect of the present invention, a semiconductor device having a wiring line which is composed of a first insulating film formed on inner walls of a groove which is formed in a surface of a semiconductor substrate, and a first conductive layer embedded in a concave portion formed by the first insulating film. In this case, the first conductive layer may be formed of at least one of metal, metal silicide and impurity-doped polysilicon.

In yet still another aspect of the present invention, a method of manufacturing a semiconductor device, is attained by (a) forming grooves in a surface of a semiconductor substrate, wherein inner walls other than a top portion near to the surface of the semiconductor substrate in each of the grooves are covered by a first insulating film; by (b) forming a first conductive layer on the first insulating film in each of the grooves; by (c) forming a second conductive layer on the first conductive layers in each of the grooves to have extending portions from the groove into portions of the semiconductor substrate corresponding to the top portion; by (d) forming a second insulating film on the second conductive layers and the surface of the semiconductor substrate; and by (e) forming a third conductive layer on the second insulating film to cross over the grooves.

The grooves may be formed in the surface of a semiconductor substrate, and thermal treatment may be carried out to form the first insulating film on the surface of the semiconductor substrate and the inner walls of each of the grooves, and then the first insulating film may be removed from the surface of the semiconductor substrate and the top portions of the inner walls of the grooves.

Also, it is desirable that each of the grooves has a depth in a range of 200 to 500 nm.

The formation of the first conductive layer may be attained by (f) depositing the first conductive layer; and by (g) removing the first conductive layer from the surface of the semiconductor substrate and the top portions of the grooves. In this case, the (g) removing may be attained by removing the first conductive layer from the top portions of the grooves such that a remaining of the first conductive layer in the grooves is a thickness in a range of 100 to 250 nm from the surface of the semiconductor surface.

Also, the first conductive layer may be formed of at least one of metal, metal silicide and impurity-doped polysilicon.

The formation of the second conductive layer may be attained by (h) forming the second conductive layer on the surface of the semiconductor substrate and the first conductive layer and the first insulating film in the grooves; by (i) removing the second conductive layer from the surface of the semiconductor substrate such that the second conductive layer is remained in each of the grooves; and by (j) carrying out thermal treatment to form the extending portions. In this case, the (j) carrying out may be attained by carrying out solid phase diffusion of impurity from the second conductive layer into the portions of the semiconductor substrate corresponding to the top portions to form the extending portions. Also, the (j) carrying out may be attained by carrying out either of the thermal treatment for 10 to 30 minutes at a temperature of 850° C. by an electronic furnace or the thermal treatment for 5 to 15 seconds at a temperature of 800 to 1000° C. by a lamp annealing method.

Also, the (d) formation of the second insulating film may be attained by carrying out thermal oxidation to form the second insulting film functioning as a gate insulating film.

Also, the semiconductor device may be a flat cell type ROM, the first and second conductive layers function bit lines. In this case, the third conductive layer functions as a word line, and a surface region of the semiconductor substrate between the grooves functions as a channel region of a flat cell type cell transistor. In this case, the method may be further include forming a photoresist layer on an interlayer insulating film formed on the semiconductor substrate and the third conductive layer; patterning the photoresist layer based on data to be written; and carrying out ion implantation of impurity for a same conductive type as a conductive type of the semiconductor substrate to change a threshold voltage.

### BRIEF DESCRIPTION OF THE DRAWINGS

FIGS. 1A and 1B are cross sectional views of a cell transistor having a MOS structure;

FIGS. 2A and 2B are a plan view and an equivalent circuit diagram of a flat cell type semiconductor memory device, respectively;

FIG. 3A to FIG. 3J are cross sectional views of a cell transistor of a memory cell in the flat cell type semiconductor memory device according to an embodiment of the present invention in order of a manufacturing process;

FIGS. 4A and 4B show an expanded plan view and a cross sectional view of the cell transistor of the flat cell type semiconductor memory device of the present invention along the line B-B in the process shown in FIG. 4A; and

FIGS. 5A and 5B are cross sectional views showing a wiring line such as a bit line to which the present invention is applied.

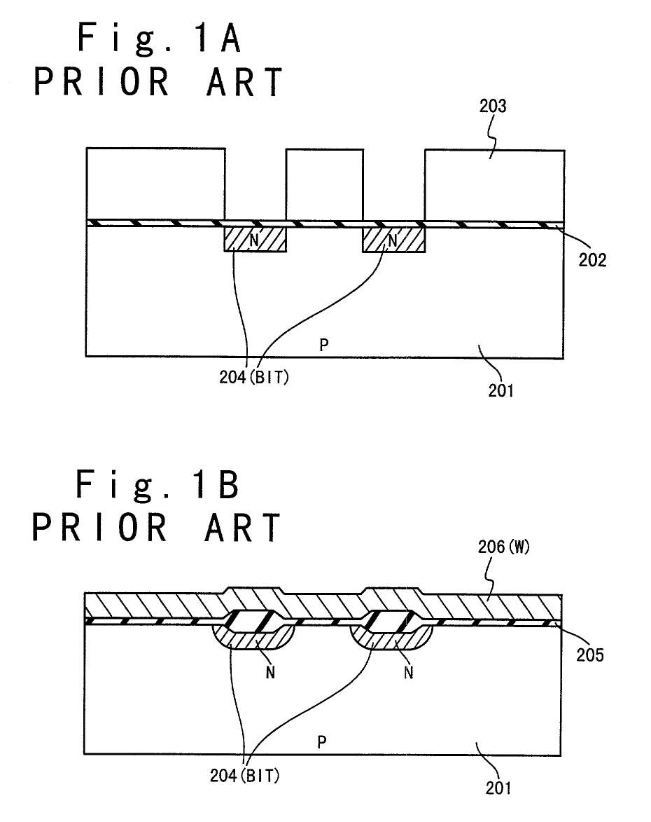

### DESCRIPTION OF THE PREFERRED EMBODIMENTS

Next, a semiconductor memory device of the present invention such as a flat cell type semiconductor memory device will be described with reference to the attached drawings.

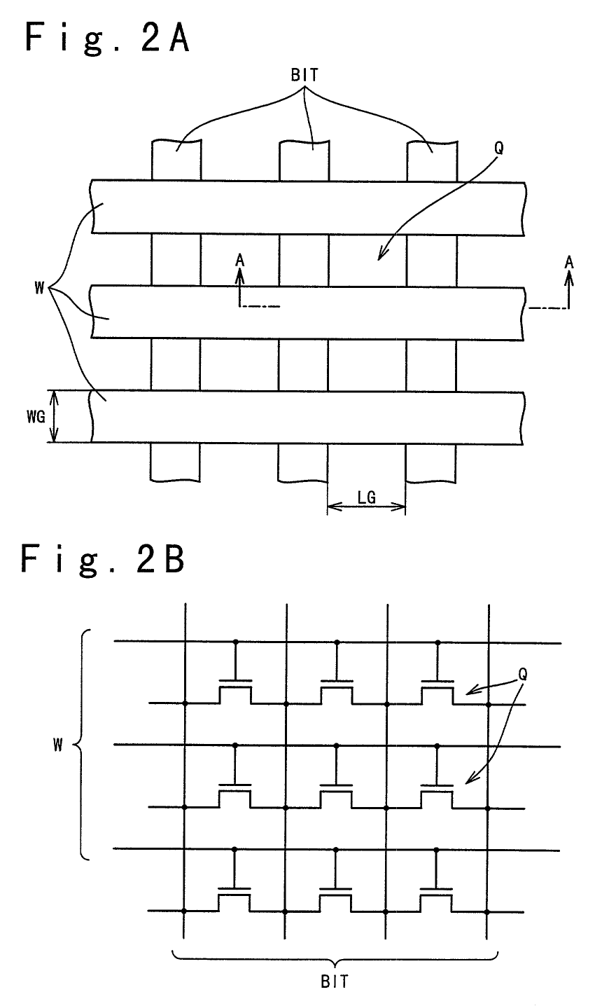

FIGS. 2A and 2B are a plan view and an equivalent circuit diagram of the flat cell type ROM. Referring to FIGS. 2A and 2B, the source and drain regions as N-type diffusion layers are arranged in a Y direction on a P-type silicon substrate with a predetermined interval as bit lines Bit. Also, gate electrodes of polycide films, that is, word lines W are arranged in an X direction on the silicon substrate with a predetermined interval to intersect the bit lines Bit. A cell transistor Q having a MOS structure is formed in the region which contains each of the intersection points of the bit lines Bit and the word lines W. It should be noted that P-type impurity regions with a comparatively high density are formed for separation between the cell transistors in regions other than the region for the bit lines Bit and the word lines W. In this structure, the gate length LG of the cell transistor Q is equal to the interval between the bit lines Bit and a gate width WG is equal to the width of the word line W.

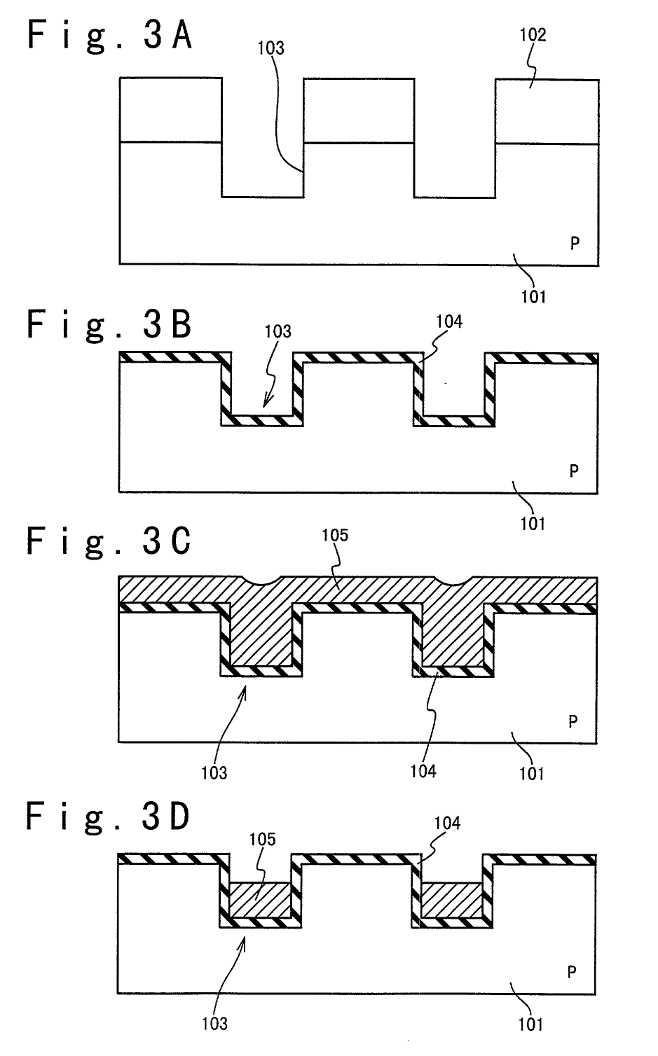

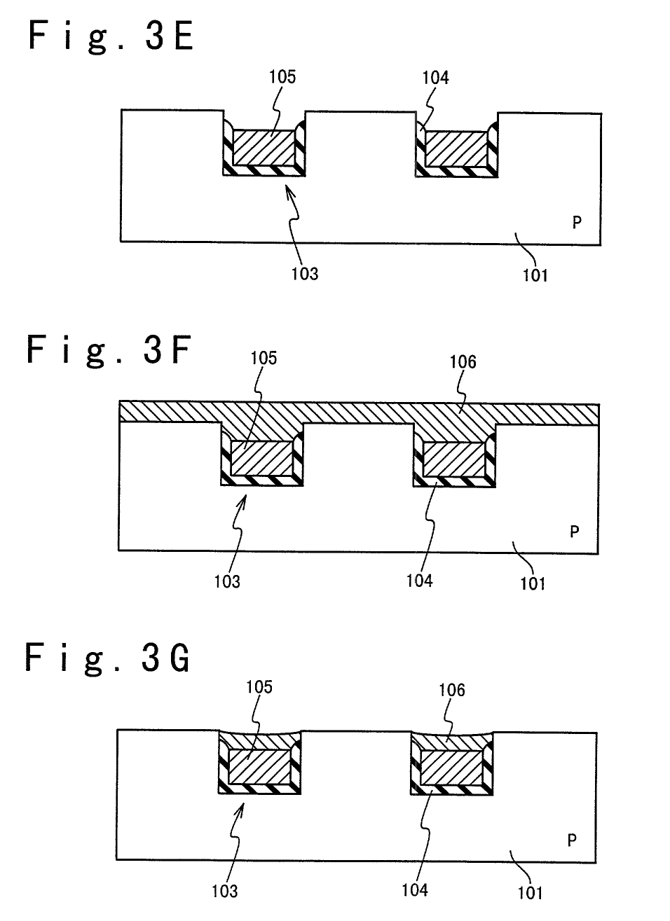

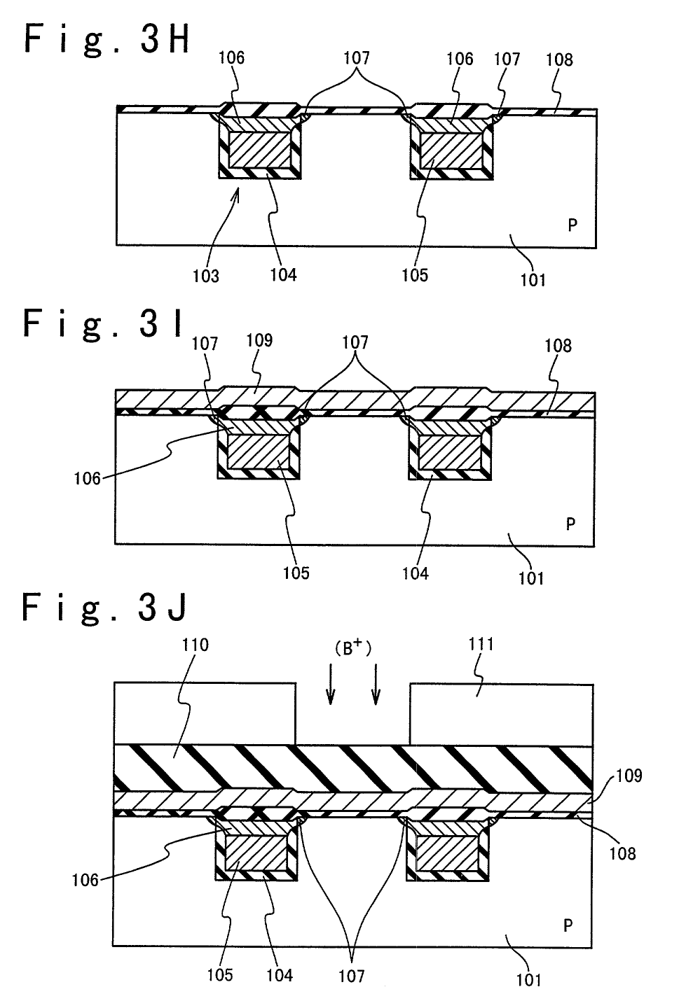

FIG. 3A to FIG. 3J are cross sectional views of a cell transistor of a memory cell in a flat cell type semiconductor memory device such as a ROM according to an embodiment of the present invention in order of the manufacturing process. It should be noted that the cross sectional views show the section structure of the flat cell type ROM along the line A-A shown in FIG. 2A.

First, as shown in FIG. 3A, a photo-resist film, an oxide film or a nitride film is formed on a P-type silicon substrate 101. Opening portions are formed in the regions of the film as a mask 102 corresponding to the source and drain regions. Subsequently, a plasma etching is carried out to the exposed surface of the silicon substrate 101 through the openings of the mask 102 to form shallow grooves 103 with the width of 200 nm and the depth of 200 to 500 nm. Subsequently, as shown in FIG. 3B, after the mask 102 is removed, a thermal oxidation process is carried out to the exposed surface of the silicon substrate 101 to form the oxide film 104 with the thickness of 20 to 40 nm. At this time, inner walls of the grooves are covered with the oxide film 104. Subsequently, as shown in FIG. 3C, a metal film 105 of metal such as tungsten is deposited by a CVD method to cover the oxide film 104 on the silicon substrate 101 and to fill the shallow groove 103. After that, as shown in FIG. 3D, the metal film 105 is etched back so that the metal films 105 are remained in the shallow grooves 103 in an embedded state. In this embodiment, an etching time is adjusted in such a manner that the film thickness of the remaining metal film 105 is about 100 to 250 nm.

Next, as shown in FIG. 3E, the metal film 105 is used as a mask and the oxide film 2 is etched back. At this time, the etching back is carried out until the oxide film 104 on the silicon substrate in the neighborhood of the openings is removed, that is, until the surface of the semiconductor substrate 101 is exposed in a region other than the shallow grooves 103. In this embodiment, the etching time is adjusted in such a manner that the top surface of the oxide film 104 in the shallow groove 103 is located to have the depth of 50 to 200 nm from the surface of the silicon substrate 101. Subsequently, as shown in FIG. 3F, a polysilicon film containing N-type impurity such as phosphor, i.e., a DOPOS film 106 is formed by a CVD method on the surface of the silicon substrate 101. The DOPOS film 106 has a film thickness sufficient to cover the surface of the shallow groove 103 and the silicon substrate 101. Subsequently, as shown in FIG. 3G, the DOPOS film 106 is etched back so that the DOPOS film 106 is left on the metal film 105 and the top surfaces of the insulating film 104 in the shallow groove 103. At this time, the DOPOS film 106 has the height approximately equal to the surface of the silicon substrate 101.

Next, as shown in FIG. 3H, a thermal treatment process is carried out for 10 to 30 minutes at the temperature of 850° C. by an electric furnace in a nitrogen atmosphere, or for 5 to 15 seconds at the temperature in a range of 800° C. to 1100° C. by a lamp annealing method. As a result, the N-type impurity in the DOPOS film 106 is diffused in solid phase into the silicon substrate 101. Thus, N-type impurity solid phase diffusion layers 107 are formed in the surface region of the silicon substrate 101 corresponding to a region where the DOPOS film is formed on the insulating film 104 in the shallow groove 103. The bit line (the source or drain region) Bit as a wiring line shown in FIG. 2A is formed of the DOPOS film 106, the metal film 105 and the N-type impurity solid phase diffusion layers 107.

Next, as shown in FIG. 3H, thermal oxidation is carried out to the surface of the silicon substrate 101 to form a gate oxide film 108 with the thickness of 5 to 15 nm. At this time, since the surface of the DOPOS film 106 has a larger oxidation rate than the surface of the silicon substrate 101 so that the oxidization is accelerated there, the film thickness of the oxide film 108 is thicker than the other region. Subsequently, a polysilicon film is deposited on the oxide film 108 to have the thickness of 100 to 200 nm by a CVD method. Then, phosphorus impurity is diffused in a high density for the polysilicon film to have a low resistivity. Then, a polycide film 109 is formed by depositing a silicide of high melting point metal by a sputtering method. The silicide film has the thickness of 100 to 200 nm. Subsequently, the polycide film 109 is patterned by an etching method by use of photolithography technique and a photoresist. Thus, the word line (gate electrode) W is formed as showed in FIG. 2A.

Next, P-type impurity is ion-implanted on the whole surface of the silicon substrate 101 in a lower density than those of the DOPOS film 106 and the N-type impurity solid phase diffusion layer 107. Since the DOPOS film 106 and the N-type impurity solid phase diffusion layer 107 are N-type impurity region with the higher density, the influence by the ion implantation of the P-type impurity exists hardly. Also, the P-type impurity is ion-implanted using the gate polycide 109 as a mask. Therefore, the P-type device separation region is formed in a self-alignment manner in a region other than the gate polycide 109 and the source and drain regions 106 and 107. In this way, the cell transistor of the flat cell type according to the present invention is formed.

As shown in FIG. 3J, an interlayer insulating film 110 is formed on the silicon substrate 101 and the polycide film 109. Then, contacts are selectively formed to pass through to the source and drain regions for a process for forming so-called mask ROM with the cell transistor.

Also, a photoresist film 111 is formed on the interlayer insulating film 110. An opening is formed in the photo-resist layer 111 above the gate region of the cell transistor to be set to the OFF state. Then, P type impurity such as boron is ion-implanted in the channel region of the cell transistor from the opening through the interlayer insulating film 110, the polycide film 109 and the gate oxide film 108. Thus, the threshold voltage of the cell transistor in which P-type impurity is implanted is changed. After that, the photo-resist layer 111 is removed, and wiring line layers and a passivation film are formed to complete the mask ROM.

As described above, the flat cell type memory device of the present invention is advantageous in shortening the manufacturing period of a mask ROM desired by a customer, since a writing operation to the ROM, i.e., ROM coding can be carried out after forming of the interlayer insulating film.

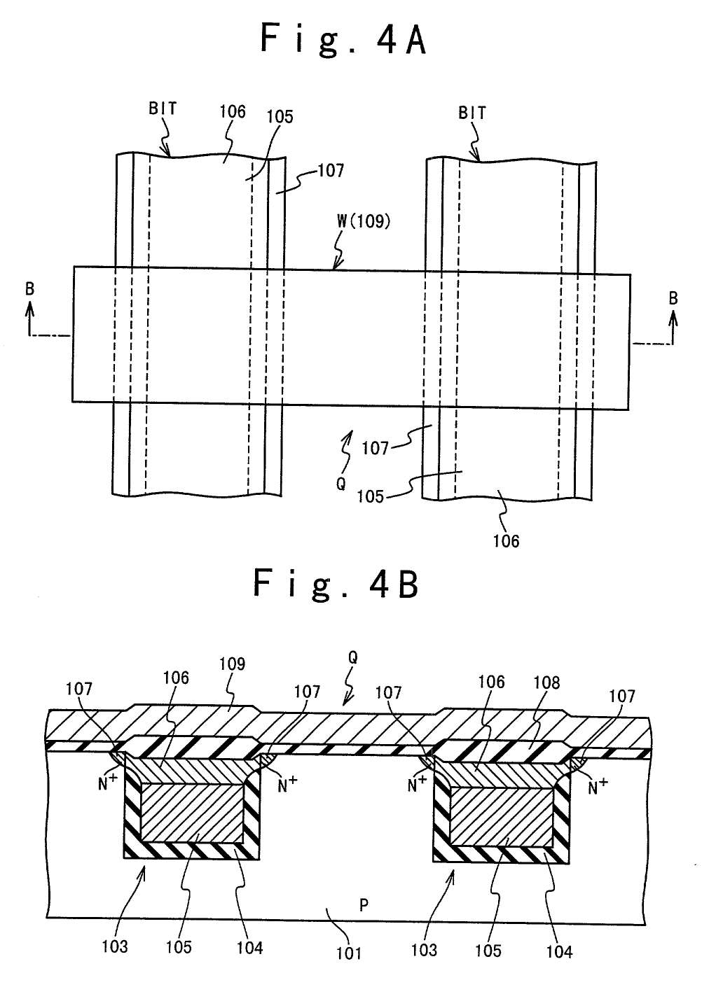

In this way, FIGS. 4A and 4B show an expanded plan view and a cross sectional view of the cell transistor Q of the flat cell type ROM of the present invention along the line B-B in the process shown in FIG. 4A. The source and drain regions as bit lines Bit is composed of the metal film 105 embedded in the shallow groove 103, the DOPOS film 106 formed on the metal film 105 and the insulating film 104, and the N-type impurity solid phase diffusion layers 107 which is formed through solid phase diffusion from the DOPOS film 106 toward the channel region. Therefore, even when the interval between the bit lines Bit, i.e., the source and drain regions is made narrow in accordance with the reduction of design rule, the bit line Bit can be made to have low resistance by the metal film 105 embedded in the shallow groove 103. As a result, it is possible to increase the access speed of the memory cell. Especially, if the shallow groove 103 is formed to have a deeper depth, the metal film 105 can be formed thicker so that the further lower resistance can be realized.

Also, the N-type impurity solid phase diffusion layers 107 which determines the effective channel length of each cell transistor Q are composed of the N-type impurity layers formed through the solid phase diffusion from the DOPOS film 106 in the shallow groove 103 into the surface region of the silicon substrate 101. Therefore, in the formation of the N-type impurity solid phase diffusion layers 107, the diffusion into the direction of the depth and the direction of the side can be restrained and the control of the diffusion through the heat-treatment becomes easy. In this way, the N-type impurity solid phase diffusion layer 107 shallow in depth and small in size can be realized, so that it is possible to prevent the narrow effective effect channel length and to restrain leak current.

Also, the DOPOS film 106 is in the state isolated from the silicon substrate by the oxide film 104 and the metal film 105 in the shallow groove 103. Therefore, there is no case that the N-type impurity in the DOPOS film 106 diffuses from the side or bottom of the shallow groove 103 to the silicon substrate 101. Also, there is no case that the shallow groove 103 is expanded in the width of the bit line so that the leak current increases in this region.

In the above embodiment, the metal film 105 is embedded in the shallow groove 103 in the process of FIG. 3D. However, it is possible to form the low resistance layer of an impurity-doped polysilicon film, a metal silicide film or a combination of at least two of the metal film, the impurity-doped polysilicon film and the metal silicide, if the film has etching selectivity from the oxide film in the shallow groove and the silicon substrate. Especially, when the polysilicon film is formed, another polysilicon film containing impurity may be selectively formed on the surface of the polysilicon film to fill the shallow groove 103. Also, the oxide film 104 in the shallow groove 103 may be formed of another insulating film such as a nitride film.

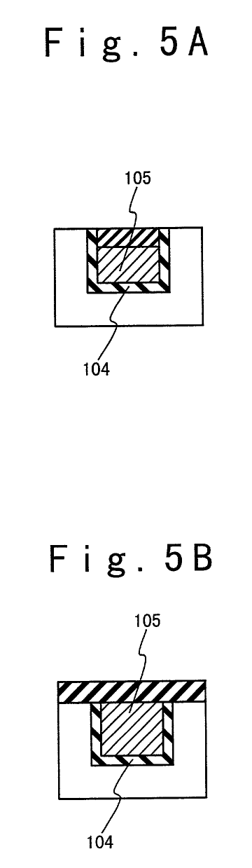

Also, the present invention can be applied to a wiring line such as a bit line, as shown in FIGS. 5A and 5B. As shown in FIG. 5A, in case of the wiring line, the insulating film 104 is remained to reach the surface of the semiconductor substrate in the etching back process. After a part of the concave portion formed by the insulating film 104 is filled with the metal film 105, a top empty region above the metal film 105 may be filled with another insulating film. Alternatively, as shown in FIG. 5B, the insulating film 104 is remained to reach the surface of the semiconductor substrate in the etching back process. Subsequently, the whole concave portion formed by the insulating film 104 may be filled with the metal film 105. Then, another insulating film is formed on the semiconductor substrate, the insulating film 104 and the metal film 105.

As described above, according to the semiconductor device of the present invention, even if the width of the source or drain region as the bit line is reduced in accordance with the reduction of the design rule, the resistance of the bit line never becomes high, because the low resistance film is embedded in the shallow groove, resulting in high speed access to the memory cell.

Also, an impurity ion implantation process and an activation heat treatment process are not used for forming the source and drain regions. The semiconductor film containing impurity is subjected to only the heat treatment process for the solid phase diffusion. Therefore, a relatively shallow impurity region can be formed in the semiconductor substrate under well control, so that it is possible to prevent the reduction of the effect channel length, resulting in reduction of leak current.

What is claimed is:

1. A semiconductor device comprising:
a first insulating film formed on inner walls other than a top portion of each of grooves which are formed in a surface of a semiconductor substrate, said top portion being near to the surface of said semiconductor substrate;
a first conductive layer formed to fill a concave portion to the surface of said semiconductor substrate and to having a portion extending from said top portion into a portion of said semiconductor substrate, wherein said concave portion is formed by said first insulating film in each of said grooves, and said first conductive layers function as source and drain regions;
a gate insulating film formed to cover said first conductive layer and said semiconductor substrate; and
a gate electrode formed on said gate insulating film to form a MOS transistor.

2. The semiconductor device according to claim 1, wherein said first conductive layer comprises:
a second conductive layer in said concave portion;
a third conductive layer on said second conductive layer and said first insulating film in said groove; and
said extending portion formed by solid phase diffusion of impurity from said third conductive layer.

3. The semiconductor device according to claim 2, wherein said second conductive layer is formed of at least one of metal, metal silicide and impurity-doped polysilicon.

4. The semiconductor device according to claim 2, wherein said third conductive layer is formed of impurity-doped polysilicon.

5. The semiconductor device according to claim 1, wherein said semiconductor device comprises:
a plurality of said grooves which extend in a direction orthogonal to said gate electrode, said first conductive layers functioning as bit lines; and
a plurality of said gate electrodes parallel to each other, and
wherein a flat cell type transistor is formed at a region where every two of said plurality of grooves intersect one of said plurality of gate electrodes.

6. The semiconductor device according to claim 5, wherein said semiconductor device is a mask ROM.

7. A semiconductor device comprising:
a first conductive layer embedded in each of grooves formed in a surface portion of a semiconductor substrate;
a second conductive layer formed on said first conductive layer in each of said grooves, said first and second conductive layers functioning as either of a source region and a drain region;
a gate insulating film formed to cover said second conductive layer and said semiconductor substrate; and
a gate electrode formed on said gate insulating film to form a MOS transistor.

8. The semiconductor device according to claim 7, wherein said second conductive layer further comprises:
extending conductive portions, each of which extends from a top portion of said second conductive layer into said surface portion of said semiconductor substrate.

9. The semiconductor device according to claim 8, wherein a region between said extending conduction portions of said grooves adjacent to each other functions as a channel region.

10. The semiconductor device according to claim 7, wherein said first conductive layer is formed of at least one of metal, metal silicide and impurity-doped polysilicon.

11. The semiconductor device according to claim 10, wherein said second conductive layer is formed of impurity-doped polysilicon.

12. The semiconductor device according to claim 7, wherein said first conductive layer is formed in a concave portion which is formed by an insulating film formed on inner walls of each of said grooves.

13. The semiconductor device according to claim 7, wherein said semiconductor device comprises:
a plurality of said grooves which extend in a direction orthogonal to said gate electrode, said first conductive layers functioning as bit lines; and
a plurality of said gate electrodes parallel to each other, and
wherein a flat cell type transistor is formed in a region where every two of said plurality of grooves intersect one of said plurality of gate electrodes.

14. The semiconductor device according to claim 13, wherein said semiconductor device is a mask ROM.

15. A semiconductor device having a wiring line which comprises:
a first insulating film formed on inner walls of a groove which is formed in a surface of a semiconductor substrate; and
a first conductive layer embedded in a concave portion formed by said first insulating film.

16. The semiconductor device according to claim 15, wherein said first conductive layer is formed of at least one of metal, metal silicide and impurity-doped polysilicon.

17. A method of manufacturing a semiconductor device, comprising:
(a) forming grooves in a surface of a semiconductor substrate, wherein inner walls other than a top portion near to the surface of said semiconductor substrate in each of said grooves are covered by a first insulating film;
(b) forming a first conductive layer on said first insulating film in each of said grooves;
(c) forming a second conductive layer on said first conductive layers in each of said grooves to have extending portions from said groove into portions of said semiconductor substrate corresponding to said top portion;
(d) forming a second insulating film on said second conductive layers and the surface of said semiconductor substrate; and
(e) forming a third conductive layer on said second insulating film to cross over said grooves.

18. The method according to claim 17, wherein said (a) forming includes:
forming said grooves in the surface of a semiconductor substrate;
carrying out thermal treatment to form said first insulating film on the surface of the semiconductor substrate and the inner walls of each of said grooves; and
removing said first insulating film from the surface of the semiconductor substrate and said top portions of the inner walls of said grooves.

19. The method according to claim 17, wherein each of said grooves has a depth in a range of 200 to 500 nm.

20. The method according to claim 17, wherein said (b) forming includes:
(f) depositing said first conductive layer; and
(g) removing said first conductive layer from the surface of the semiconductor substrate and said top portions of said grooves.

21. The method according to claim 20, wherein said (g) removing includes:
removing said first conductive layer from said top portions of said grooves such that a remaining of said first conductive layer in each groove has a thickness in a range of 100 to 250 nm.

22. The method according to claim 20, wherein said first conductive layer is formed of at least one of metal, metal silicide and impurity-doped polysilicon.

23. The method according to claim 17, wherein said (c) forming includes:
(h) forming said second conductive layer on the surface of the semiconductor substrate and said first conductive layer and said first insulating film in said grooves;
(i) removing said second conductive layer from the surface of the semiconductor substrate such that said second conductive layer is remained in each of said grooves; and
(j) carrying out thermal treatment to form said extending portions.

24. The method according to claim 23, wherein said (j) carrying out includes:
carrying out solid phase diffusion of impurity from said second conductive layer into said portions of said semiconductor substrate corresponding to said top portions to form said extending portions.

25. The method according to claim 23, wherein said (j) carrying out thermal treatment includes:
carrying out either of said thermal treatment for 10 to 30 minutes at a temperature of 850° C. by an electronic furnace or said thermal treatment for 5 to 15 seconds at a temperature of 800 to 1000° C. by a lamp annealing method.

26. The method according to claim 17, wherein said (d) forming includes:
carrying out thermal oxidation to form said second insulting film functioning as a gate insulating film.

27. The method according to claim 17, wherein said semiconductor device is a flat cell type ROM, said first and second conductive layers function bit lines, said third conductive layer functions as a word line, and a surface region of said semiconductor substrate between said grooves functions as a channel region of a flat cell type cell transistor.

28. The method according to claim 27, further comprising:
forming a photoresist layer on an interlayer insulating film formed on said semiconductor substrate and said third conductive layer;
patterning said photoresist layer based on data to be written; and
carrying out ion implantation of impurity for a same conductive type as a conductive type of said semiconductor substrate to change a threshold voltage.
